(19) United States
(12) Patent Application Publication
(10) Pub. No.: US 2025/0028253 A1
(43) Pub. Date: Jan. 23, 2025

(54) METHOD FOR DETECTING DEFECTS IN SEMICONDUCTOR STRUCTURE AND METHOD FOR CLASSIFYING SEMICONDUCTOR STRUCTURE

(71) Applicant: TAIWAN SEMICONDUCTOR MANUFACTURING COMPANY LTD., HSINCHU (TW)

(72) Inventors: YEN-FONG CHAN, HSINCHU COUNTY (TW); PEI-HSUAN LEE, TAIPEI CITY (TW); XIAOMENG CHEN, HSINCHU COUNTY (TW)

(21) Appl. No.: 18/509,343

(22) Filed: Nov. 15, 2023

Related U.S. Application Data
(60) Provisional application No. 63/514,803, filed on Jul. 21, 2023.

(51) Int. Cl. G03F 7/00; G01N 23/04; G01N 23/2206; G01N 23/2252; G01N 23/227; H01L 21/66

(52) U.S. Cl. CPC G03F 7/7065; G01N 23/04; G01N 23/2206; G01N 23/2252; G01N 23/227; G03F 7/70655; H01L 22/14; G01N 2223/41; G01N 2223/6116; G01N 2223/6462

(57) ABSTRACT

A method for detecting defects in a semiconductor structure is provided. The method includes the following operations. A semiconductor structure having a plurality of conductive structures is received. An electron beam inspection operation is performed on the plurality of conductive structures of the semiconductor structure to obtain an inspection data, wherein a pulsed electron beam utilized in the electron beam inspection operation is selected from the group consisting of a nanosecond pulsed beam, a picosecond pulsed beam, and a femtosecond pulsed beam. A first conductive structure having a non-open defect is identified from the inspection data. A method for classifying semiconductor structure is also provided.

### CROSS REFERENCE TO RELATED APPLICATION

This application claims the benefit of prior-filed U.S. provisional application No. 63/514,803, filed Jul. 21, 2023, under 35 U.S.C. 120.

### BACKGROUND

Fabricating semiconductor devices, such as logic and memory devices, typically includes processing a substrate such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etch, deposition, and ion implantation.

Inspection processes are used at various steps during a semiconductor manufacturing process to detect defects on wafers or reticles to promote higher yield in the manufacturing process and thus higher profits. However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary since even relatively small defects may cause unwanted aberrations in the semiconductor devices. Furthermore, as design rules shrink, semiconductor manufacturing processes may be operating closer to the limitations on the performance capability of the processes, and smaller defects can have an impact on the electrical parameters of the device.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor structure according to some embodiments of the present disclosure.

FIG. 2 illustrates schematic view of a scanning electron microscopy (SEM) system according to some embodiments of the present disclosure.

FIG. 3 illustrates a flow chart of detecting defects in a semiconductor structure according to some embodiments of the present disclosure.

FIG. 4 illustrates a chart of inspection data according to some comparative embodiments of the present disclosure.

FIG. 5 illustrates a chart of inspection data according to some embodiments of the present disclosure.

FIG. 6 illustrates a flow chart of detecting defects in a semiconductor structure according to some embodiments of the present disclosure.

FIG. 7 illustrates a flow chart of classifying a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

The IC manufacturing process flow can be typically divided into three categories: front-end-of-line (FEOL), middle-end-of-line (MEOL), and back-end-of-line (BEOL). FEOL generally encompasses processes related to fabricating IC devices, such as transistors. For example, FEOL processes can include forming isolation features, gate structures, and source and drain features (generally referred to as source/drain features). MEOL generally encompasses processes related to fabricating contacts to conductive features (or conductive regions) of the IC devices, such as contacts to the gate structures and/or the source/drain features. BEOL generally encompasses processes related to fabricating interconnect structures that interconnect IC features fabricated by FEOL processes and MEOL processes, thereby enabling the operation of the IC devices.

In semiconductor manufacturing processes, defects that occur within the structures formed by metal materials in the MEOL (middle-end-of-line) and BEOL (back-end-of-line) stages can result in an increase in electrical resistance. This heightened resistance can have detrimental effects on semiconductor devices and their overall performance.

For instance, a common type of defect in metal structures involves the presence of impurities, such as foreign materials or contaminants. These impurities can infiltrate the metal layers during the deposition process, subsequently disrupt the flow of electrons within the metal, creating localized areas of increased electrical resistance. Such a situation may result in reduced conductivity, slower signal transmission, and potential performance degradation in semiconductor devices.

Another type of defect is the formation of voids or gaps within the metal structures. These voids can interrupt the continuous conductive path, effectively increasing the resistance along the affected regions. As current passes through these areas of higher resistance, it may generate heat and hence potentially resulting in hotspots. These hotspots can lead to device failure, reduced reliability, and impaired functionality.

Furthermore, the metal layers in the BEOL structure primarily serve to interconnect various components of the semiconductor device. Defects in these interconnects, such as open circuits or shorts, can have an adverse impact on electrical resistance. For instance, the open circuits disrupt the current flow, leading to increased resistance and signal disruption, while the shorts create unintended connections, altering the intended electrical pathways and potentially resulting in functional failures and decreased performance.

In order to inspect semiconductor structures for defects, there are some techniques widely used in the semiconductor manufacturing industry, such as optical inspection, electron microscopy, X-ray inspection, acoustic microscopy, electrical testing, laser scanning inspection, thermography, non-destructive testing (NDT), etc.

Among some common inspection approached, optical inspection generally involves the use of visible or ultraviolet light to visually examine semiconductor surfaces. It is effective in detecting surface defects such as scratches, particles, and irregularities. Optical microscopes and specialized inspection tools are commonly employed for this purpose. However, optical inspection is constrained by the wavelength of visible or ultraviolet light, which limits its ability to detect very small defects or features at the nanoscale. Consequently, it is less effective in identifying sub-micron defects or those within the internal layers of semiconductor structures. Furthermore, optical inspection primarily focuses on the surface of semiconductor materials, making it less suitable for detecting defects buried within the material or located beneath multiple layers. In other words, this technique provides limited information depth, as it cannot offer insights into the three-dimensional structure of defects or their depth within the material.

In another approach, X-ray inspection, including X-ray diffraction (XRD) and X-ray photoelectron spectroscopy (XPS), can be employed to analyze the crystal structure, composition, and chemical properties of semiconductor materials. However, similar to the issues with optical inspection, X-ray inspection is also constrained by the wavelength of X-rays, limiting its spatial resolution. It may struggle to accurately detect very small defects or nanoscale features, especially when compared to higher-resolution techniques like electron microscopy. Moreover, achieving higher resolution in X-ray imaging often involves exposing samples to higher doses of radiation, which may not be suitable for delicate or sensitive semiconductor devices.

In some embodiments of the present disclosure, a method for detecting defects within a semiconductor structure, such as defects in the metal structures in the MEOL and the BEOL structures of the semiconductor structures, can be employed. In some embodiments of the present disclosure, the detection approach is based on techniques such as scanning electron microscopy (SEM) or electron beam inspection (EBI). These related techniques utilize electron beams to examine and inspect various materials, including said semiconductor structures, at the microscale and nanoscale levels.

The EBI is a sophisticated and highly versatile imaging and analysis technique widely used in the semiconductor industry to scrutinize and assess semiconductor materials, integrated circuits, and other microelectronic devices. Briefly, it can be employed for defect detection, precise metrology (measurement of critical dimensions), contamination analysis, and failure analysis. The detection resolution of the EBI is high enough to detect tiny physical defects beyond the ability of optical defect imaging systems, and the EBI can be used to detect electrical defects of integrated circuitry, such as an open defect, a short or a leakage defect underneath the wafer surface by detecting voltage contrast (VC) due to the surface charge induced gray level (GL) variation.

The EBI operates on the principle of utilizing a focused electron beam to meticulously investigate the surface and subsurface features of semiconductor samples, enabling the detection of defects, measurement of critical dimensions, and analysis of material composition. EBI may be used to ensure the quality and reliability of semiconductor products, as even tiny defects or deviations from specifications can have a profound impact on the performance of electronic devices.

One of the primary principles of the EBI involves the generation of a focused electron beam using a high-energy electron gun, similar to the electron microscopes (e.g., SEM) used in scientific research. This electron beam is incredibly fine and can be precisely controlled, allowing it to scan semiconductor samples with exceptional precision. As the electron beam interacts with the sample, it gives rise to various interactions, including electron-sample interactions and electron scattering, which produce emitted signals and secondary electrons from the sample's surface. Specialized detectors are employed to capture these signals, which are subsequently processed to generate high-resolution images and data regarding the sample's topography, morphology, composition, and the presence of defects.

One of the standout features of the EBI is its exceptional spatial resolution, which allows it to discern and analyze sub-micron features and defects on semiconductor surfaces. This level of detail is crucial in semiconductor manufacturing, where even the tiniest irregularities can impair device functionality and reliability. Furthermore, the EBI is non-destructive, meaning it does not harm the sample during the inspection process. This is vital in semiconductor production, where the integrity of the devices must be preserved throughout the manufacturing process.

The EBI also offers the capability to perform subsurface imaging, making it invaluable for identifying defects and structures hidden beneath the surface of semiconductor materials. This capability is especially beneficial in pinpointing defects that may not be readily visible from the surface but can still impact device performance.

To be more detailed, in the aspect of defect detection, the EBI is used to identify and locate a variety of imperfections, including particles, cracks, voids, and electrical shorts on semiconductor wafers and ICs. Detecting defects at an early stage is crucial for improving yield and ensuring the overall quality of semiconductor products. In metrology, the EBI is utilized to precisely measure critical dimensions and verify that semiconductor devices conform to design specifications. This is essential for maintaining consistent device performance and functionality. Furthermore, the EBI can analyze contaminants on the surface of semiconductor materials, helping manufacturers identify and mitigate sources of contamination that can compromise device reliability. In the event of a semiconductor device failure, the EBI is instrumental in conducting failure analysis. By examining the structure of the semiconductor device and identifying defects or anomalies that may have contributed to the failure, the EBI aids in diagnosing and resolving issues to prevent future failures.

In some embodiments of the present disclosure, the open defect in the semiconductor structure can be detected through the EBI. In semiconductor structures, the term “open defect” refers to a type of defect that occurs when there is an interruption or discontinuity in the electrical path within the structure. It can be caused by various factors such as manufacturing errors, material defects, or physical damage.

That is, in the circumstances that a semiconductor structure has an open defect, it means that there is a physical gap or a physical missing connection in the electrical circuitry. This can happen at different portions within the semiconductor structure, such as at the metal lines or metal vias (i.e., within the BEOL structure), or at or in proximity to the transistor portion (i.e., within the FEOL structure or the MEOL structure). The open defect may create a break in the circuit, disrupt the normal flow of electrons, and prevent the flow of current through the affected region, thus lead to a loss of functionality or performance degradation in the semiconductor device.

The impact of an open defect depends on its location and the circuit it affects. For instance, if the open defect occurs in a critical path of the circuit, it can lead to a complete failure of the semiconductor device. On the other hand, if the open defect is in a non-critical path, it may result in reduced performance or intermittent failures.

Furthermore, in the aspect of parameters of the semiconductor structure, the open defect would increase the resistance of the path of the circuit. The resistance of an open defect is can vary depending on the nature of the interruption, and can be influenced by factors such as the size of the defect, the material properties, and the surrounding environment. Nevertheless, comparing to the resistance of a normal conductive structure with stable signal, the resistance of the open defect is extremely high. In some examples, the resistance of the conductive structure having the open defect is greater than about 1×10⁶ ohms or greater than about 1×10⁷ ohms, which is about 80% to about 90% higher than the resistance of a normal conductive structure in the semiconductor structure.

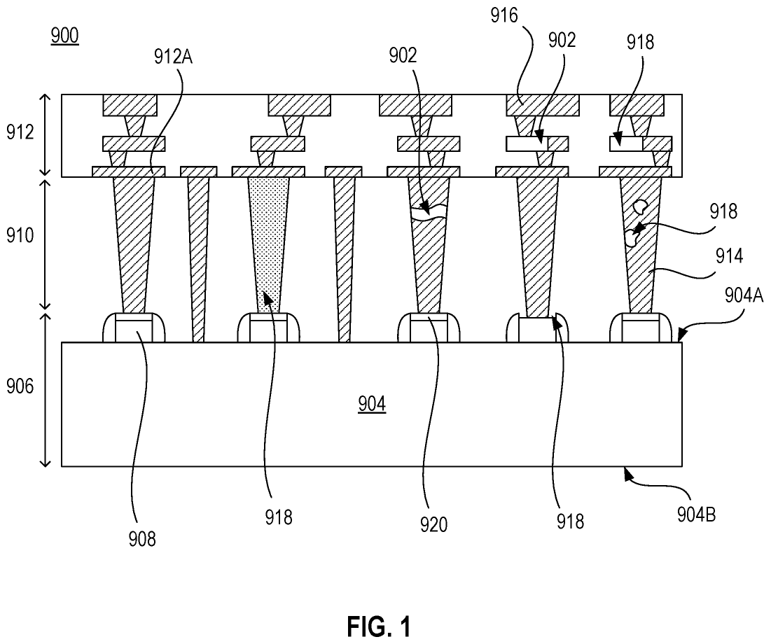

Referring to FIG. 1, in some embodiments, the semiconductor structure 900 includes one or more open defects 902 therein. As shown in the figure, the semiconductor structure 900 may include a substrate 904 having a first side 904A and a second side 904B opposite to the first side 904A. The substrate 904 may include a semiconductor material such as silicon or germanium. In other examples, the substrate 904 may include other semiconductor materials, such as silicon germanium, silicon carbide, gallium arsenide, gallium phosphide, indium phosphide, indium arsenide, indium antimonide, or combinations thereof. The substrate 904 may include a front-end-of-line (FEOL) structure 906 at the first side 904A. The FEOL structure 906 is the first portion of IC fabrication where the active components such as transistors 908 are formed at the first side 904A of the substrate 904. In addition, a middle-end-of-line (MOL/MEOL) structure 910 and/or a back-end-of-line (BEOL) structure 912 are formed over the FEOL structure 906. Generally, the MEOL structure 910 is the structure that formed over the FEOL structure 906 and prior to the formation of the BEOL structure 912. The definitions of what is properly considered MEOL structure 910 may vary, whereas in some embodiments of the present disclosure, the MEOL structure 910 is referred to the region that formed over the first side 904A of the substrate 904 and below a first metal layer (Ml) 912A of the BEOL structure 912. The dielectric material formation in the MEOL structure 910 is referred to pre-metal dielectric (PMD) formation.

In some embodiments, there are a plurality of conductive structures such as conductive contacts 914 in the MEOL structure 910 configured to provide the electrical connection between the transistors 908 and the metal lines 916 in the BEOL structure 912. Some of the conductive contacts 914 are landed on the doped regions (i.e., a part of the transistors 908, not shown in the figure) in the substrate 904. Due to some manufacturing errors, some conductive contacts 914 may have open defects 902 that disrupt the flow of electrons.

Other than the conductive contact 914 having the open defect 902, the semiconductor structure 900 may further includes one or more non-open defects 918 that different from the open defects 902.

In semiconductor structures, a “non-open defect” refers to a type of defect that does not result in a complete break or interruption in the circuitry. As some examples shown in FIG. 1, unlike the open defect 902, which causes a complete discontinuity in the electrical path, the non-open defect 918 may still allow some level of current flow through the affected region. However, this non-open defect can still have implications for the performance and reliability of the semiconductor device. Particularly, with the continuous evolution of technology nodes in semiconductor manufacturing process, it is imperative to acknowledge the profound impact of non-open defects on the ongoing miniaturization of semiconductor structure sizes. These non-open defects have now attained the classification of “killer” defects due to their substantial influence on the performance of semiconductor devices.

To be more detailed, the non-open defects can occur due to various reasons during the fabrication process of semiconductor devices. These non-open defects can be caused by issues such as contamination, impurities, or errors in the deposition or etching processes. In some embodiments, the non-open defects can be caused by the bottom residue and thus increase the resistance of the metal via in the BEOL structure 912. The non-open defects can manifest as localized variations in the material properties, such as changes in the doping concentration, the thickness, or the crystal structure. The impact of a non-open defect on the performance of a semiconductor structure depends on its location, size, and the functionality of the affected region. Overall, even though the non-open defect may not completely disrupt the electrical path, it can still introduce unwanted resistive elements into the circuit.

The resistance of a non-open defect can vary depending on its characteristics. The non-open defect may introduce a localized increase in resistance, causing a voltage drop across the affected region. This additional resistance can lead to increased power consumption, reduced signal quality, a loss of signal strength, a decrease in the voltage available for driving subsequent circuitry, and therefore degraded device performance. Comparing to the resistance of the normal conductive structure with stable signal, the resistance of the non-open defect is high (but not as high as the open defect since the non-open defect is not a complete break or interruption in the circuitry). In some examples, the resistance of the conductive structure having the non-open defect is in a range of from about 1×10³ ohms to about 1×10⁶ ohms, which is about 30% to about 50% higher than the resistance of a normal conductive structure in the semiconductor structure.

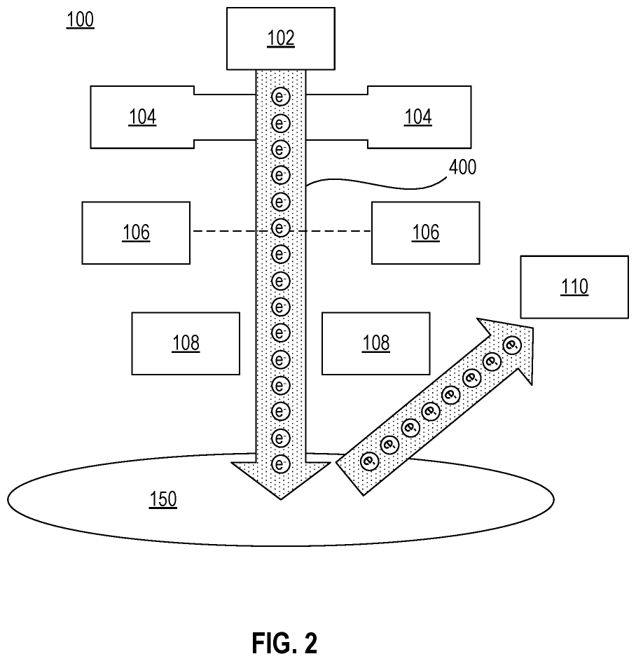

In some embodiments, in order to detect the defects that having abnormal resistance in the semiconductor structure, the EBI system can be employed. In some embodiments, referring to FIG. 2, a SEM system 100 (e.g., a field emission-scanning electron microscopy (FE-SEM)) that belong to the field of EBI system is employed to perform the electron beam inspection operation. In some embodiments, the SEM system 100 includes an electron source 102, which is typically a heated tungsten filament, solid state hexaboride crystals, or a field emission gun (FEG). The electron source 102 emits an electron beam 400 that will be focused and scanned across the surface of the sample 150. A typical example of the sample 150 is a semiconductor wafer, such as the wafer having the semiconductor structure 900 previously shown in FIG. 1.

In some embodiments, the electron source 102 in the SEM system 100 includes a photocathode 104, which serves as the initial stage in the generation of the electron beam 400 used for imaging specimens at high resolution. The operation of the photocathode 104 relies on the principles of the photoelectric effect. For instance, when illuminated with light, typically ultraviolet (UV) or laser light, the photocathode 104 may absorb photons and emit electrons. This phenomenon is possible because the energy of the incoming photons exceeds the work function of the material of the photocathode 104, allowing them to dislodge electrons from the surface of the photocathode 104. The emitted electrons, known as photoelectrons, are then extracted from the photocathode 104 and subsequently focused into a narrow and intense electron beam. This process is facilitated by the electron gun that applies an electric field to accelerate and shape the photoelectrons into a coherent beam. The coherent beam can then be accurately directed and scanned across the specimen's surface to interact with it and generate various signals, including secondary electrons (SE), backscattered electrons (BSE), and characteristic X-rays. These signals are detected and utilized to construct highly detailed images and gather valuable information about the specimen's topography, composition, and other properties. The material of the photocathode 104 depends on factors such as the desired sensitivity to specific wavelengths of light, stability, and efficiency. In some embodiments, the material of the photocathode 104 includes cesium antimonide (Cs₃Sb), which exhibits a low work function and sensitivity to visible and UV light.

In some embodiments, the electron source 102 further includes an anode 106, typically in the form of a positively charged electrode positioned near the photocathode 104. The positive electric potential at the anode 106 creates an electrostatic field that attracts and accelerates the emitted electrons, propelling the photoelectrons away from the photocathode 104. This acceleration imparts kinetic energy to the electrons, resulting in the formation of a focused electron beam. The role of the anode 106 in this acceleration process is essential for achieving the desired beam characteristics, including energy and focus, thereby enabling high-resolution imaging capabilities in the SEM system 100.

In some embodiments, the SEM system 100 further includes an electron lens 108, which is positioned along the route of the electron beam 400 after the anode 106. The electron lens 108 serves as a crucial optical component responsible for focusing and directing the electron beam 400, enabling the SEM to achieve high-resolution imaging and analytical capabilities. In some embodiments, the electron lens 108 may include electromagnetic coils or magnetic lenses that generate magnetic fields. These magnetic fields interact with the moving electrons, causing them to follow a curved path due to the Lorentz force. By precisely adjusting the strength and orientation of these magnetic fields, the electron lens 108 can control the convergence or divergence of the electron beam 400. This control may achieve the desired beam characteristics, including focus and spot size, which directly impact image quality and resolution.

Furthermore, in some embodiments, a detector 110 can be positioned near the sample 150 (e.g., a wafer having the semiconductor structure 900) to collect and analyze the signals generated by the interaction of the electron beam 400 with the sample. Some of the common detectors include the secondary electron detectors, the backscattered electron detectors, and the energy-dispersive X-ray spectroscopy (EDS) detectors.

To be more detailed, when the electron beam strikes the surface of the sample 150, there are several interactions may thus occur and lead to the emission of various signals, such as (a) the secondary electrons: these low-energy electrons are emitted from the surface of the sample 150 due to the excitation caused by the primary electron beam, and the secondary electron detectors may collect these electrons to generate high-resolution images, providing topographical information; (b) the backscattered electrons: these are high-energy electrons that are deflected backward after interacting with the atomic nuclei of the sample 150, and the backscattered electron detectors may capture these electrons, providing compositional and crystallographic information about the sample; and (c) the X-ray emission: when the primary electron beam interacts with the sample 150, it can cause the emission of characteristic X-rays, and the EDS detectors may analyze these X-rays to determine the elemental composition of the sample 150.

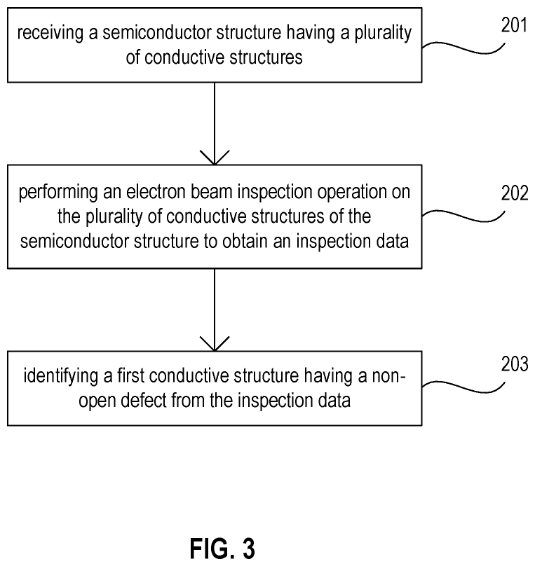

Under the usage of the SEM system 100, referring to FIG. 3, in some embodiments, the method for detecting defects in the semiconductor structure may include: an operation 201: receiving a semiconductor structure having a plurality of conductive structures; an operation 202: performing an electron beam inspection operation on the plurality of conductive structures of the semiconductor structure to obtain an inspection data; and an operation 203: identifying a first conductive structure having a non-open defect from the inspection data. Particularly, in some embodiments, the pulsed electron beam utilized in the electron beam inspection operation is selected from a group consisting of a nanosecond pulsed beam, a picosecond pulsed beam, and a femtosecond pulsed beam. In some embodiments, the current of the pulsed electron beam is about 10 mA, maximum.

To be more detailed, as the semiconductor structure 900 previously illustrated in FIG. 1 of the present disclosure, the semiconductor structure 900 may include a plurality of conductive structures such as the conductive contacts 914 that usually made of tungsten, the titanium silicide (TiSi₂) layer 920 that used to provide low-resistance path for the electrical current between the transistor 908 and the metal interconnects (e.g., the metal lines 916), the metal-to-diffusion (MD) layer that used to create ohmic contacts between different components in the semiconductor structure 900, and the metal-to-gate layer. These conductive structures can be examined to determine the presence of physical defects. In some embodiments, in addition to the conductive structures mentioned above, which are typically found in the FEOL structure and the MEOL structure, it is also possible to detect the metal vias and the metal lines within each of the metal layers in the BEOL structures.

In some embodiments, the electron beam inspection operation is performed after the MEOL structure 910 is formed over the substrate 904, and therefore the conductive structure having the non-open defect can be identified from the titanium silicide layer 920 or the metal-to-diffusion (MD) layer in the MEOL structure 910, if there is any. In other embodiments, the electron beam inspection operation is performed after the BEOL structure 912 is formed over the MEOL structure 910, and therefore the non-open defect in the BEOL structure 912 can be identified accordingly, if there is any.

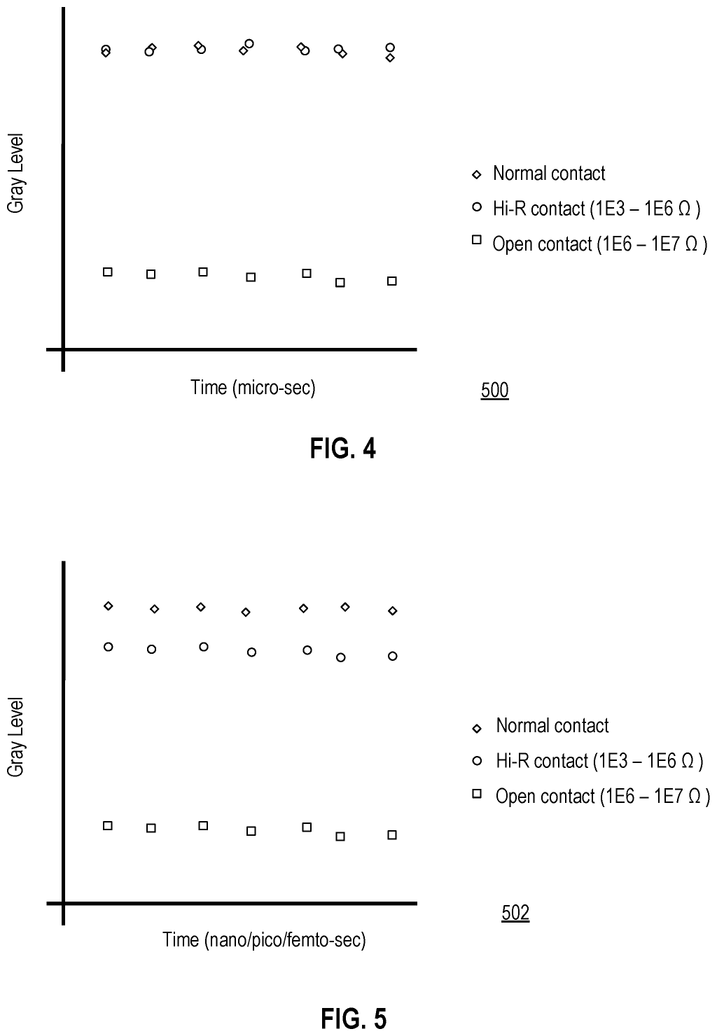

Referring to FIG. 4, in some comparative embodiments, the EBI systems based on a field emitter (FE) gun source (e.g., the FE-SEM system) may provide an inspection data 500 output with a response time within microseconds. Furthermore, commercially available FE-SEM systems typically lack pulsed beam capability to offer response times faster than microseconds. When using these EBI systems, as shown in the inspection data in FIG. 4, it is not possible to distinguish the gray level of the conductive structure having the non-open defect from the gray level of the conductive structure free from having defect in the sample (i.e., the defect-free conductive structure or normal conductive structure). In other words, the EBI systems using a microsecond pulsed beam are unable to detect non-open defects.

Furthermore, from other aspect, oxide charging is often occurring around the conductive structures such as conductive contacts and cause the non-open defects (if there are any) unstable and behave in a transient state, so that the detection of the non-open defects is obscured.

Accordingly, in some embodiments of the present disclosure, when performing the electron beam inspection on the plurality of conductive structures within the semiconductor structure to obtain inspection data, the response time of the pulsed electron beam used in the electron beam inspection can be accelerated to a level shorter than microseconds for detecting non-open defects. In other words, the microsecond (1×10⁻⁶ s) pulsed beam typically used in electron beam inspection can be replaced with a nanosecond (1×10⁻⁹ s) pulsed beam, a picosecond (1×10⁻¹² s) pulsed beam, or even a femtosecond (1×10⁻¹⁵ s) pulsed beam, by using the FE-SEM systems that modified to offer response times faster than microseconds.

Referring to FIG. 5, in some embodiments, the EBI systems based on a FE gun source may provide an inspection data 502 output with a response time within nanoseconds, picoseconds, or femtoseconds, wherein the scale of the time-axis in the inspection data 502 can be adjusted for convenience of interpretation. By using one of the pulsed beams having the response time shorter than microseconds, the gray level of the conductive structure having the non-open defect can be distinguished from the gray level of the conductive structure free from having defect. That is, the signals regarding the existence of the non-open defects can be visualized illustrated from the inspection data, and the conductive structure having the non-open defect can thus be identified therefrom.

In some embodiments, as shown in FIG. 5, the conductive structure having the non-open defect (e.g., the Hi-R contact, which means the resistance is high but not as extremely high as that of the open contact) is detectable because the gray level of the conductive structure having the non-open defect is substantially less than the gray level of the conductive structure free from having defect (e.g., the normal contact, or called defect-free contact) and greater than the gray level of the conductive structure having the open defect (e.g., the open contact).

In some embodiments, the method for detecting defects in the semiconductor structure is implemented under the circumstances that the resistances of the conductive structures with/without defect are different, and the resistances of the types of open/non-open defects are also different. In some embodiments, the resistance of the conductive structure having the non-open defect is in a range of from about 1×10³ ohms to about 1×10⁶ ohms, whereas the conductive structure having the open defect is in a range of from about 1×10⁶ ohms to about 1×10⁷ ohms, or even more.

In some embodiments, the resistance of the conductive structure having the non-open defect (e.g., the Hi-R contact) is falls within that is approximately 30% to 50% higher than the resistance of the defect-free conductive structure (e.g., the normal contact). In contrast, the resistance of the conductive structure with an open defect (e.g., the open contact) falls within a range that is approximately 80% to 90% higher than the resistance of the defect-free conductive structure (e.g., the normal contact). In other words, in some embodiments, the method for detecting defects in the semiconductor structure can be applied in cases where the resistance of the conductive structure with the open defect is at least 20% higher than the resistance of the conductive structure with the non-open defect. Essentially, the method described in the present disclosure is capable of distinguishing defects with at least a 20% difference in resistance.

Regarding the selection of the response time of the pulsed electron beam, in some embodiments, the selection of the pulsed electron beam in the electron beam inspection operation is determined by whether the gray level of the conductive structure with the non-open defect in the inspection data is distinguishable from the gray level of the conductive structure free from having defect in the inspection data. Since a typical semiconductor structure may have multiple conductive structures with open defects, non-open defects, or be defect-free, in some embodiments, the response time of the pulsed electron beam used in the electron beam inspection operation can be adjusted to different levels to determine which pulsed beam is fast enough to accurately distinguish between the signals from non-open defects and those that are defect-free.

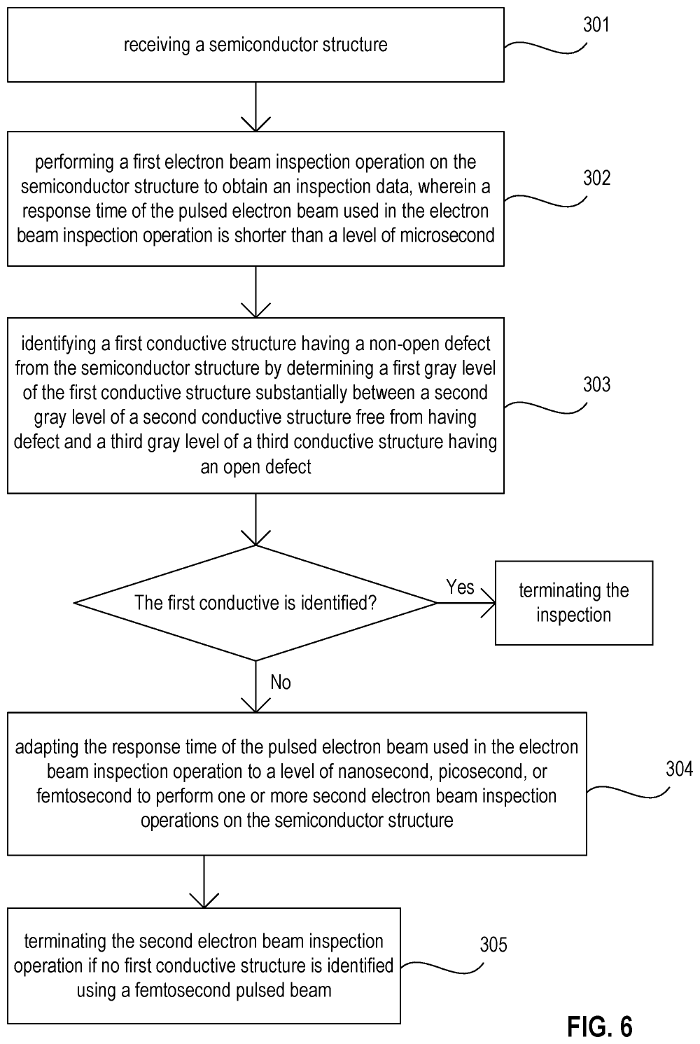

Accordingly, referring to FIG. 6, in some embodiments, the method for detecting defects in the semiconductor structure may include: an operation 301: receiving a semiconductor structure; an operation 302: performing a first electron beam inspection operation on the semiconductor structure to obtain an inspection data, wherein a response time of the pulsed electron beam used in the electron beam inspection operation is shorter than a level of microsecond; an operation 303: identifying a first conductive structure having a non-open defect (e.g., the Hi-R contact) from the semiconductor structure by determining a first gray level of the first conductive structure substantially between a second gray level of a second conductive structure free from having defect (e.g., the normal contact) and a third gray level of a third conductive structure having an open defect (e.g., the open contact); and an operation 304: if no first conductive structure is identified, adapting the response time of the pulsed electron beam used in the electron beam inspection operation to a level of nanosecond, picosecond, or femtosecond to perform one or more second electron beam inspection operations on the semiconductor structure. By gradually reducing the response time and thus increasing the pulse rate (e.g., in an order of the level of nanosecond, picosecond, and femtosecond), it is possible to search for and identify non-open defects in an organized and energy-efficient manner. This consideration takes into account that femtosecond pulses have a significantly shorter duration, and due to the extremely short duration, the femtosecond pulses often require higher energy levels to achieve sufficient power. Consequently, the femtosecond pulsed beams tend to consume more energy compared to the picosecond pulsed beams, as do the nanosecond pulsed beams in comparison to the picosecond pulsed beams.

Still referring to FIG. 6, in some embodiments, the method further includes an operation 305: terminating the second electron beam inspection operation if no first conductive structure is identified using a femtosecond pulsed beam. In other words, the process of distinguishing between types of defects can be terminated if no non-open defects can be distinguished from the inspection data when a femtosecond pulsed beam is employed. In such a scenario, it is highly likely that there are no non-open defects in the semiconductor structure. Naturally, if the non-open defect has already been identified in the operation 303, there is no need to adapt the response time of the pulsed electron beam, nor does to use the second electron beam.

In addition, in some embodiments of the present disclosure, the method for detecting defects in the semiconductor structure can be applied to classify the semiconductor structures to ensure that the shipped semiconductor structures are basically free from having defects (i.e., without having open defects and non-open defects). In some embodiments, the semiconductor substrates, wafers, or other semiconductor structures can be classified or based on pre-determined threshold resistance value, which means in the case of the conductive structures in the semiconductor structure having open defects or non-open defects, the resistance value of the conductive structures may excess the pre-determined threshold and thus be classified as a group that not be shipped.

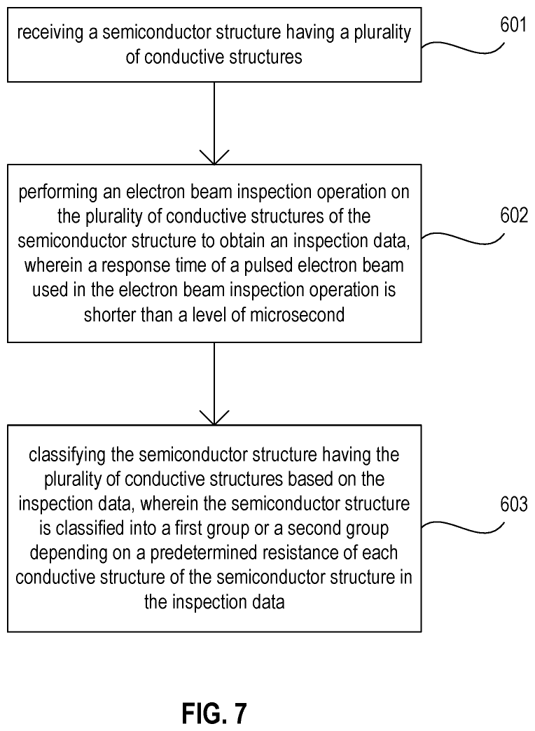

Referring to FIG. 7, in some embodiments, the method for classifying semiconductor structure may include: an operation 601: receiving a semiconductor structure having a plurality of conductive structures; an operation 602: performing an electron beam inspection operation on the plurality of conductive structures of the semiconductor structure to obtain an inspection data, wherein a response time of a pulsed electron beam used in the electron beam inspection operation is shorter than a level of microsecond; and an operation 603: classifying the semiconductor structure having the plurality of conductive structures based on the inspection data, wherein the semiconductor structure is classified into a first group or a second group depending on a predetermined resistance of each conductive structure of the semiconductor structure in the inspection data. In some embodiments, the plurality of conductive structures of the semiconductor structure classified into the first group can be those having a resistance less than about 1×10³ ohms (i.e., without having open defects and non-open defects). In some embodiments, the method further include an operation that identifying a first conductive structure having a non-open defect from the plurality of conductive structures from the inspection data by determining a first gray level of the first conductive structure substantially between a second gray level of a second conductive structure free from having defect and a third gray level of a third conductive structure having an open defect. In some embodiments, the semiconductor structure is classified into the second group if the semiconductor structure is free from having the first conductive structure and the third conductive structure in the plurality of conductive structures.

Overall, the present disclosure provide an approach in identifying the non-open defects in the semiconductor structure. By enhancing the pulsed beam capability in EBI system, the non-open defects that used to be undetectable can thus be detected. In addition, while the VC signal of the EBI system with response time is in the level of nanosecond, picosecond, and/or femtosecond, the oxide charging effect can also be diminished.

In one exemplary aspect, a method for detecting defects in a semiconductor structure is provided. The method includes the following operations. A semiconductor structure having a plurality of conductive structures is received. An electron beam inspection operation is performed on the plurality of conductive structures of the semiconductor structure to obtain an inspection data, wherein a pulsed electron beam utilized in the electron beam inspection operation is selected from a group consisting of a nanosecond pulsed beam, a picosecond pulsed beam, and a femtosecond pulsed beam. A first conductive structure having a non-open defect is identified from the inspection data.

In another exemplary aspect, a method for detecting defects in a semiconductor structure is provided. The method includes the following operations. A semiconductor structure having a plurality of conductive structures is provided. An electron beam inspection operation is performed on the plurality of conductive structures of the semiconductor structure to obtain an inspection data, wherein a response time of the pulsed electron beam used in the electron beam inspection operation is accelerated to a level shorter than microseconds. A first conductive structure having a non-open defect is identified from the inspection data.

In yet another exemplary aspect, a method for detecting defects in a semiconductor structure is provided. The method includes the following operations. A semiconductor structure is received. A first electron beam inspection operation is performed on the semiconductor structure to obtain an inspection data, wherein a response time of the pulsed electron beam used in the electron beam inspection operation is shorter than a level of microsecond. A first conductive structure having a non-open defect is identified from the semiconductor structure by determining a first gray level of the first conductive structure substantially between a second gray level of a second conductive structure free from having defect and a third gray level of a third conductive structure having an open defect. If no first conductive structure is identified, the response time of the pulsed electron beam used in the electron beam inspection operation is adapted to a level of nanosecond, picosecond, or femtosecond to perform one or more second electron beam inspection operations on the semiconductor structure.

In an additional exemplary aspect, a method for classifying semiconductor structure is provided. The method includes the following operations. A semiconductor structure having a plurality of conductive structures is received. An electron beam inspection operation is performed on the plurality of conductive structures of the semiconductor structure to obtain an inspection data, wherein a response time of a pulsed electron beam used in the electron beam inspection operation is shorter than a level of microsecond. The semiconductor structure having the plurality of conductive structures is classified based on the inspection data, wherein the semiconductor structure is classified into a first group or a second group depending on a predetermined resistance of each conductive structure of the semiconductor structure in the inspection data.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for detecting defects in a semiconductor structure, the method comprising:
receiving the semiconductor structure having a plurality of conductive structures;
performing an electron beam inspection operation on the plurality of conductive structures of the semiconductor structure to obtain an inspection data, wherein a pulsed electron beam utilized in the electron beam inspection operation is selected from a group consisting of a nanosecond pulsed beam, a picosecond pulsed beam, and a femtosecond pulsed beam; and
identifying a first conductive structure having a non-open defect from the inspection data.

2. The method of claim 1, wherein a resistance of the first conductive structure having the non-open defect is in a range of from about 1×10³ ohms to about 1×10⁶ ohms.

3. The method of claim 1, wherein the first conductive structure is a portion of a titanium silicide layer, a metal-to-diffusion (MD) layer, a metal-to-gate layer, or a back-end-of-line (BEOL) structure of the semiconductor structure.

4. The method of claim 1, wherein the inspection data at least comprises a gray level of the first conductive structure and a gray level of a defect-free conductive structure.

5. The method of claim 1, wherein the first conductive structure having the non-open defect is identified by comparing a gray level of the first conductive structure in the inspection data with gray levels of a second conductive structure free from having defect and a third conductive structure having an open defect, respectively.

6. The method of claim 5, wherein the gray level of the first conductive structure having the non-open defect is greater than the gray level of the third conductive structure having the open defect and less than the gray level of the second conductive structure free from having defect.

7. The method of claim 1, wherein the electron beam inspection is performed through a field emission-scanning electron microscopy (FE-SEM).

8. The method of claim 1, wherein a current of the pulsed electron beam is about 10 mA.

9. A method for detecting defects in a semiconductor structure, the method comprising:
providing a semiconductor structure having a plurality of conductive structures;
performing an electron beam inspection operation on the plurality of conductive structures of the semiconductor structure to obtain an inspection data, wherein a response time of a pulsed electron beam used in the electron beam inspection operation is accelerated to a level shorter than microseconds; and
identifying a first conductive structure having a non-open defect from the inspection data.

10. The method of claim 9, wherein the operation of providing the semiconductor structure comprises:
receiving a substrate; and
forming a middle-end-of-line (MEOL) structure over the substrate, wherein the first conductive structure having the non-open defect is identified from a titanium silicide layer, a metal-to-gate layer, or a metal-to-diffusion (MD) layer in the MEOL structure.

11. The method of claim 9, wherein a resistance of the first conductive structure is in a range of from about 1×10³ ohms to about 1×10⁶ ohms.

12. The method of claim 9, wherein the pulsed electron beam used in the electron beam inspection operation is selected from a group consisting of a nanosecond pulsed beam, a picosecond pulsed beam, and a femtosecond pulsed beam.

13. The method of claim 9, further comprising:
identifying a second conductive structure free from having defect from the plurality of conductive structures from the inspection data, and wherein a resistance of the first conductive structure is in a range of from about 30% to about 50% higher than a resistance of the second conductive structure.

14. The method of claim 13, wherein the selection of the pulsed electron beam in the electron beam inspection operation is determined based on whether a gray level of a first conductive structure having the non-open defect in the inspection data is distinguishable from a gray level of the second conductive structure free from having defect in the inspection data.

15. The method of claim 13, further comprising:
identifying a third conductive structure having an open defect from the plurality of conductive structures from the inspection data.

16. The method of claim 15, wherein a resistance of the third conductive structure is at least 20% higher than a resistance of the first conductive structure.

17. A method for classifying semiconductor structure, the method comprising:
receiving a semiconductor structure having a plurality of conductive structures;
performing an electron beam inspection operation on the plurality of conductive structures of the semiconductor structure to obtain an inspection data, wherein a response time of a pulsed electron beam used in the electron beam inspection operation is shorter than a level of microsecond; and
classifying the semiconductor structure having the plurality of conductive structures based on the inspection data, wherein the semiconductor structure is classified into a first group or a second group depending on a predetermined resistance of each conductive structure of the semiconductor structure in the inspection data.

18. The method of claim 17, wherein the plurality of conductive structures of the semiconductor structure classified into the first group having a resistance less than about 1×10³ ohms.

19. The method of claim 17, further comprising:
identifying a first conductive structure having a non-open defect from the plurality of conductive structures from the inspection data by determining a first gray level of the first conductive structure substantially between a second gray level of a second conductive structure free from having defect and a third gray level of a third conductive structure having an open defect,
wherein the semiconductor structure is classified into the second group if the semiconductor structure is free from having the first conductive structure and the third conductive structure in the plurality of conductive structures.

20. The method of claim 19, wherein a resistance of the third conductive structure is at least 20% higher than a resistance of the first conductive structure.
